(19) United States
(12) Patent Application Publication
(10) Pub. No.: US 2026/0182399 A1
(43) Pub. Date: Jun. 25, 2026

(54) STACKED GLASS-SILICON INTERCONNECT BRIDGE ASSEMBLIES FOR HIGH-YIELD MULTI-DIE INTEGRATED CIRCUIT ARCHITECTURES

(71) Applicant: Intel Corporation, Santa Clara, CA (US)

(72) Inventor: Telesphor Kamgaing, Chandler, AZ (US)

(73) Assignee: Intel Corporation, Santa Clara, CA (US)

(21) Appl. No.: 18/989,424

(22) Filed: Dec. 20, 2024

(51) Int. Cl. H01L 23/538; H01L 23/15; H01L 25/07

(52) U.S. Cl. CPC H10W 70/611; H10W 70/65; H10W 90/00; H10W 90/401; H10W 70/692

(57) ABSTRACT

In one embodiment, an integrated circuit package includes an assembly embedded in the package substrate that includes a bridge circuitry die to interconnect multiple integrated circuit dies of the package and an interposer coupled to the bridge circuitry die. The interposer includes high aspect ratio vias (e.g., greater than 20:1), and may be formed of glass. The assembly may be embedded within a core layer of the package substrate.

### BACKGROUND

Multi-die integrated circuit architectures may include multiple integrated circuit (IC) dies in a single package with a common substrate, and may include bridge circuitry dies in the package to interconnect the various dies with one another. In some cases, the bridge circuitry dies may include through silicon vias (TSVs) that supply signals or power through the die to the IC dies. Many of these architectures require a relatively thick core substrate; however, embedding bridge circuitry dies with TSVs in thick core substrates is generally impractical (or impossible in some cases), making it impractical to implement more compact architectures.

### BRIEF DESCRIPTION OF THE DRAWINGS

FIGS. 1A-1B illustrate an example assembly that includes an interconnect bridge circuitry die assembly and a glass interposer in accordance with embodiments of the present disclosure.

FIG. 2 illustrates an example multi-die package that includes the assembly of FIGS. 1A-1B embedded in a package substrate.

FIG. 3 illustrates another example multi-die package that includes two of the assemblies of FIGS. 1A-1B embedded in a package substrate.

FIG. 4 illustrates an example multi-die package that includes the assembly of FIGS. 1A-1B embedded in interconnect layers of a package substrate.

FIG. 5 illustrates an example multi-die package that includes the assembly of FIGS. 1A-1B embedded in a core layer of a package substrate.

FIGS. 6A-6B illustrate example systems that may incorporate the glass core architectures described herein.

FIG. 7 is a top view of a wafer and dies that may be included in a microelectronic assembly, in accordance with any of the embodiments disclosed herein.

FIG. 8 is a cross-sectional side view of an integrated circuit device that may be included in a microelectronic assembly, in accordance with any of the embodiments disclosed herein.

FIG. 9 is a block diagram of an example electrical device that may include a microelectronic assembly, in accordance with any of the embodiments disclosed herein.

### DETAILED DESCRIPTION

In current architectures, bridge circuitry dies may be included in the multi-die package to interconnect the various dies. These bridge circuitry dies may include through silicon vias (TSVs) that supply signals or power through the die to the IC dies. Typically, however, multi-die architectures may require relatively thick package substrate cores (e.g., greater than 200 um thick), causing issues for the inclusion of bridge circuitry dies with TSVs, which are usually between approximately 100-150 um thick.

For instance, the bridge circuitry dies are typically embedded within a cavity of the substrate core that is approximately the same height as the thickness of the core. The bridge circuitry die thickness, however, is usually much thinner than the thick substrate cores typically used. For example, such bridge circuity dies may be approximately 50-100 um thick in current implementations. Thus, to match the thickness of the cavity, the thickness of the die must be increased, which requires longer TSVs. Fabricating longer TSVs in a bridge die, however, may be very costly, take a significant amount of time (e.g., to etch and plate), and also cause low yields for the die. In addition, the longer via liners may combine with the TSVs to form low pass filters that limit transmission speeds in the die or package.

Accordingly, embodiments herein provide extended bridge assemblies that may be embedded within substrate cores (or other layers of an integrated circuit package substrate). The extended bridge assemblies of the present disclosure include a silicon bridge circuity die of similar thickness to current bridge circuitry dies coupled to an interposer fabricated with techniques that allow for high-yield, high-density, and/or high aspect ratio (i.e., the ratio of the via height to via diameter) vias. For instance, in certain embodiments, the interposer may be formed using a glass core substrate that allows for high aspect ratio through glass vias (TGVs), which may allow for a thicker assembly with via aspect ratios of up to or greater than approximately 20:1-40:1, which is not currently practical with silicon substrate interposers.

Accordingly, embodiments herein may allow for high density interconnects in the vertical direction in addition to the horizontal direction (e.g., as provided by the bridge circuitry die). For instance, embodiments of the present disclosure can enable omnidirectional bridges that are up to or greater than 10× thicker than typical bridge circuitry dies with TSVs. The extended bridge assembly can thus be more easily integrated within a thick package substrate core, enabling further levels of disaggregation within the package. The extended bridge assembly may include passive circuitry only or may also include active circuitries, e.g., such as voltage regulators, switches or other logic circuits used in computing or communication architectures.

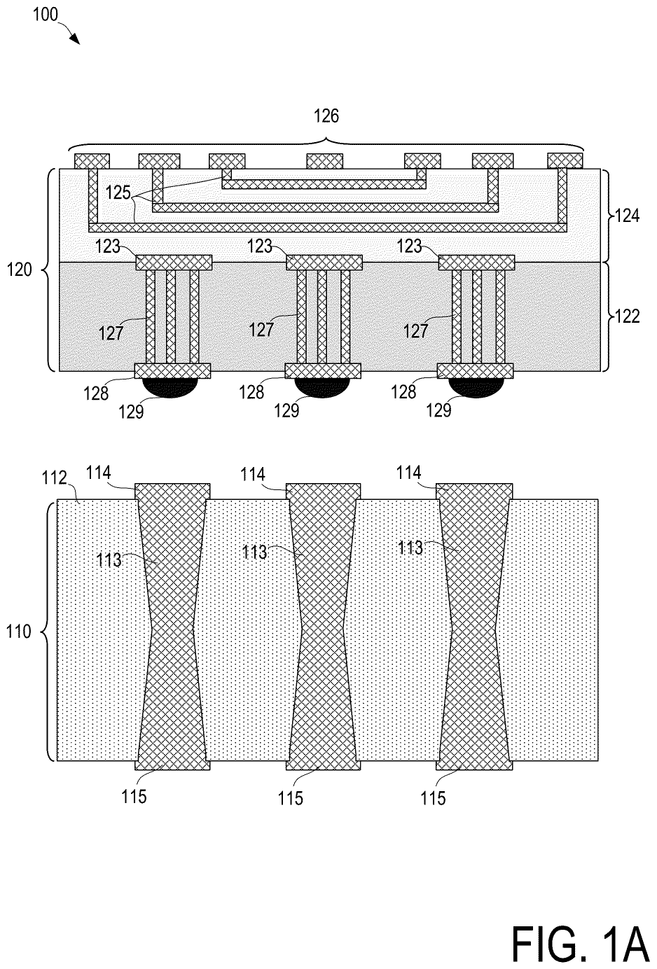

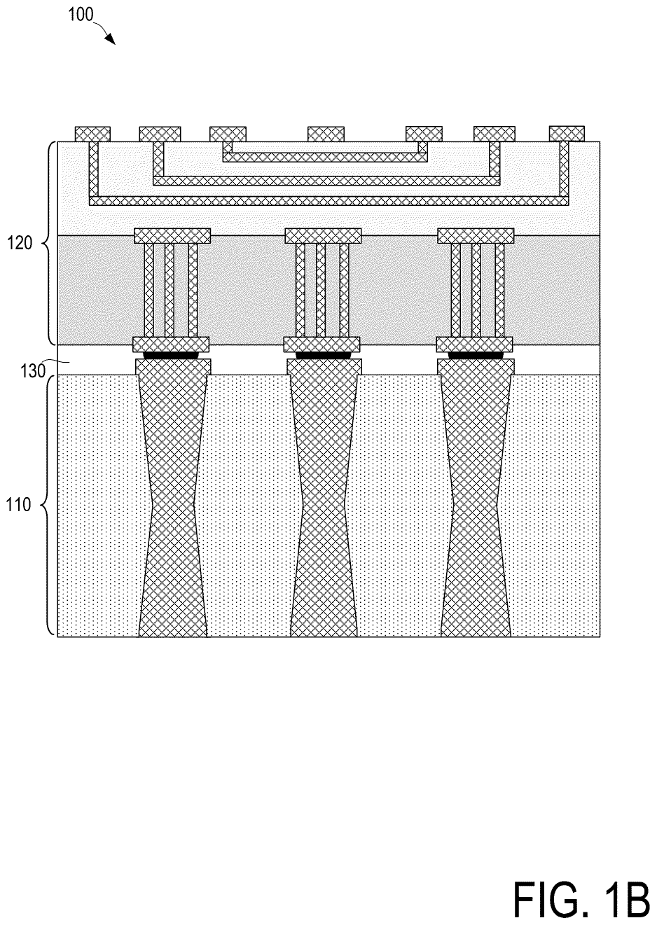

FIGS. 1A-1B illustrate an example assembly 100 that includes an interconnect bridge circuitry die 120 and a glass interposer 110 in accordance with embodiments of the present disclosure. In particular, FIG. 1A illustrates the assembly with the die 120 separate from the interposer 110 and FIG. 1B illustrates the die 120 coupled to the interposer 110.

The glass interposer 110 includes a glass substrate 112, which may include Silicon (e.g., at least 23% by weight) and Oxygen (e.g., at least 26% by weight). The glass core layer 102 may be amorphous, and in some embodiments, may include one or more additive elements (e.g., at least 5% by weight) such as Aluminum, Boron, Magnesium, Calcium, Barium, Tin, Sodium, Potassium, Strontium, Phosphorus, Zirconium, Lithium, Titanium, and Zinc. For example, the glass substrate 112 may be formed of one or more of the following example materials: aluminosilicate, borosilicate, alumino-borosilicate, silica, or fused silica. In some embodiments, the glass core layer 102 may further include one or more additives, such as, for example, Al₂O₃, B₂O₃, MgO, CaO, SrO, BaO, SnO₂, Na₂O, K2O, SrO, P₂O₃, ZrO₂, Li₂O, Ti, and Zn. In some embodiments, the glass substrate 112 may be made of a spin-on glass (SOG) material. The glass interposer 110 also includes through glass vias (TGVs) 113 that electrically couple pads 114 on the top side of the substrate 112 to pads 115 on the bottom side of the substrate 112. In some embodiments, however, the interposer 110 may be an organic material instead of glass or glass-based material.

The interconnect bridge circuitry die 120 includes a first portion 124 with interconnect traces 125 interconnecting various pads 126 on a top side of the die 120 as shown, and a second portion 122 that includes through silicon vias (TSVs) 127 connecting pads 123 and pads 128 on the bottom side of the die 120. Although shown as only including traces and vias, the die 120 may also include passive and/or active circuit components as well. The interconnect traces 125 may be designed, in certain embodiments, to interconnect two or more integrated circuit (IC) dies (e.g., as described further below) of a multi-die package. In some cases, for example, the die 120 may be an Intel® embedded multi-die interconnect bridge (EMIB)-T die that interconnects multiple integrated circuit dies coupled to the assembly 100 in a multi-die package.

As shown in FIG. 1B, the interconnect bridge circuitry die 120 may be coupled to the glass interposer 110 to provide a relatively tall overall assembly 100, which may be useful for embedding within a relatively tall substrate core (e.g., of a package substrate as described further below). The pads 128 of the die 120 couple to the pads 114 of the interposer via solder balls 129, electrically coupling the pads 126 of the die 120 to the bottom pads 115 of the interposer, which may then couple to traces or other connections of a package substrate in which the assembly 100 is embedded. After coupling, a dielectric mold material 130 (underfill) may be placed between the die 120 and the interposer 110 as shown in FIG. 1B.

In some cases, multiple interposers 110 may be formed in a glass panel or wafer. Dies 120 may then be attached to the respective interposers 110 of the panel/wafer. The attachment may be a wafer-to-wafer bonding process, or a chip-to-wafer or chip-to-panel process (which may allow for higher yields by sorting bad dies 120 before attachment). Underfill mold material (130) may be placed between the interposers and dies. The newly formed assemblies 100 may then be singulated and, for example, embedded into multi-die packages as described herein.

Although illustrated with certain pads, traces, etc., it will be understood that the assembly 100 may be fabricated in any suitable manner with different numbers of pads, vias, pitches, etc., or with a different number and/or size of TGVs (e.g., may include TGVs of different aspect ratios than shown as the illustrations are not necessarily to scale). In addition, the thickness of the interposer 110 as compared with the die 120 may be different than shown, as it may have a particular thickness that is dependent on a particular application. For instance, in some cases, the same bridge circuitry die design may be implemented in different applications by placing the die onto interposers of different thicknesses or with different TGVs, etc. Further, while various conductive contacts are illustrated herein as pads (e.g., pads 114, 115, 123, 126, 128), it will be understood that other embodiments may implement different types of conductive contacts.

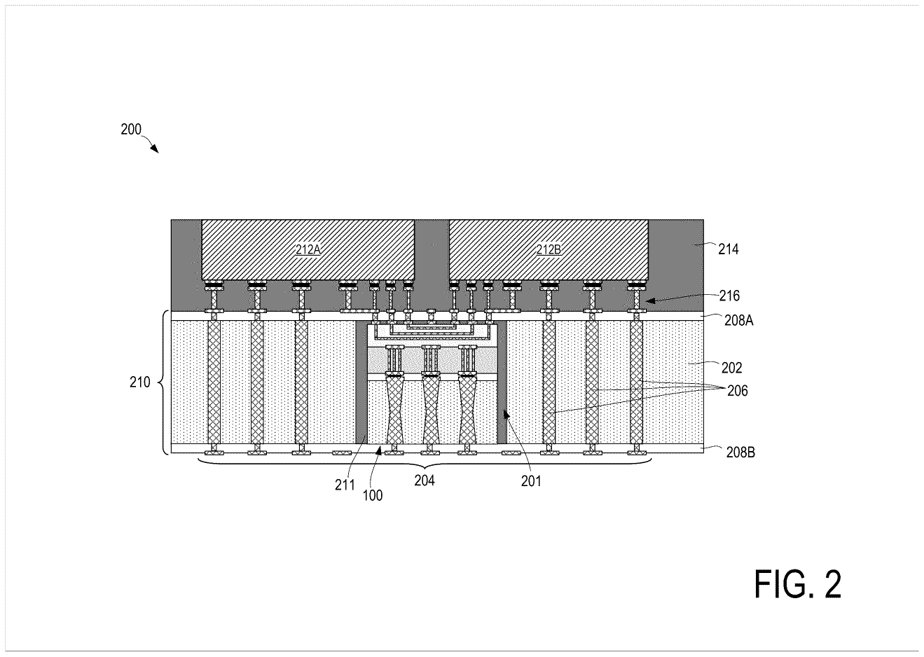

FIG. 2 illustrates an example multi-die package 200 that includes the assembly 100 of FIGS. 1A-1B embedded in a package substrate 210. In particular, the package 200 includes two integrated circuit dies 212A, 212B coupled to a substrate 210 with a thick core 202 (e.g., greater than 200 um in thickness). In some embodiments, the core 202 may be formed of glass or a glass-based material. In other embodiments, the core 202 may be formed of an organic material.

The substrate 210 defines a cavity 201 in which the assembly 100 is embedded and then encapsulated within a dielectric encapsulant material 211, e.g., mold material, epoxy, liquid crystal polymer, or other similar materials. The encapsulant material 211 may have a high thermal conductivity and/or appropriate coefficient of thermal expansion (CTE), and such material may be chosen based on the active/passive nature of the bridge circuitry within the assembly 100 and/or the type of semiconductor material used. As illustrated, the thickness of the assembly 100 may be approximately the same as the thickness of the core 202 (e.g., the assembly 100 may have a thickness of 90-105% of the thickness of the core 202). As an example, the core 202 and assembly 100 may have a thickness of approximately 250 um, while the bridge circuitry die of the assembly is between approximately 50-100 um.

As shown, the assembly 100 interconnects the dies 212A, 212B with one another and also interconnects the dies 212A, 212B with certain pads 204 at the bottom side of the substrate 210, as previously described. The substrate 210 further includes vias 206 that connect the dies 212A, 212B with other of the pads 204 at the bottom of the substrate 210. The dies 212A, 212B are connected to the vias 206 and other electrical traces within the substrate 210 (not shown for simplicity) via a number of traces 216 (which may be referred to as redistribution layers (RDL) in certain cases). The dies 212A, 212B and traces 216 are encapsulated in a dielectric encapsulant material 214 (e.g., a mold material) as shown.

The vias 206 of the substrate 210 are connected to the traces 216 through vias in the dielectric layer 208A and connected to the pads 204 through vias in the dielectric layer 208B, as shown. In some embodiments, the package 200 may be coupled to a circuit board via the pads 204 at the bottom of the substrate 210, e.g., a motherboard or main board of a computing system, in a similar manner to the multi-die package 614 is coupled to the circuit board 612 as described below. For example, in some embodiments, the package 200 may be implemented in a server, notebook computer, desktop computer, or various types of handheld computing and communication devices.

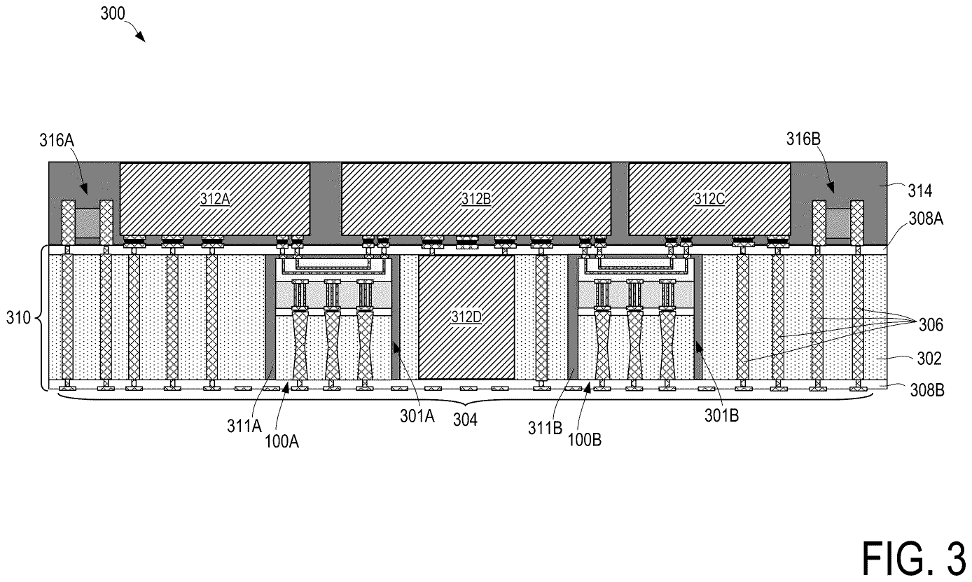

FIG. 3 illustrates another example multi-die package 300 that includes two of the assemblies 100 of FIGS. 1A-1B embedded in a package substrate 310. The example package 300 may be built, in certain embodiments, using wafer level assembly. The package 300 includes three integrated circuit dies 312A-C coupled to a substrate 310 with a thick core 302 (e.g., greater than 200 um in thickness). In some embodiments, the core 302 may be formed of glass or a glass-based material. In other embodiments, the core 302 may be formed of an organic material. In some embodiments, for example, the die 312A may be a central processing unit (CPU), the die 312B may be an input/output (IO) hub, and the die 312C may be a graphics processing unit (GPU). However, the dies 312 may be implemented in another manner than shown.

The substrate 310 defines two cavities 301A, 301B in which the assemblies 100A, 100B, respectively, are embedded and then encapsulated within a dielectric encapsulant material 311A, 311B, which may be similar to the material 211 above. The encapsulant material may have a high thermal conductivity and/or appropriate coefficient of thermal expansion (CTE), and such material may be chosen based on the active/passive nature of the bridge circuitry within the assemblies 100 and/or the type of semiconductor material used. In addition, the substrate 310 includes another die 312D embedded within the core 302. The die 312D may be implemented as a voltage regulator (VR) die, memory die, or a die with certain passive circuitry (e.g., capacitors or inductors).

As shown, the assembly 100A interconnects the dies 312A, 312B with one another and also interconnects the dies 312A, 312B with certain pads 304 at the bottom side of the substrate 310. Similarly, the assembly 100B interconnects the dies 312B, 312C with one another and also interconnects the dies 312B, 312C with other pads 304 at the bottom side of the substrate 310. The substrate 310 further includes vias 306 that connect the dies 312A-C with still other of the pads 304 at the bottom of the substrate 310. The dies 312A-C are encapsulated in a dielectric encapsulant material 314 (e.g., a mold material) as shown.

In some embodiments, the package 300 may be coupled to a circuit board, e.g., a motherboard or main board of a computing system, in a similar manner to the multi-die package 614 is coupled to the circuit board 612 as described below. For example, in some embodiments, the package 300 may be attached directly to a printed circuit board without an intermediate package substrate, interposer, etc. The package 300 may be implemented in a handheld computing devices, such as notebook computers, tablets, or smart phones.

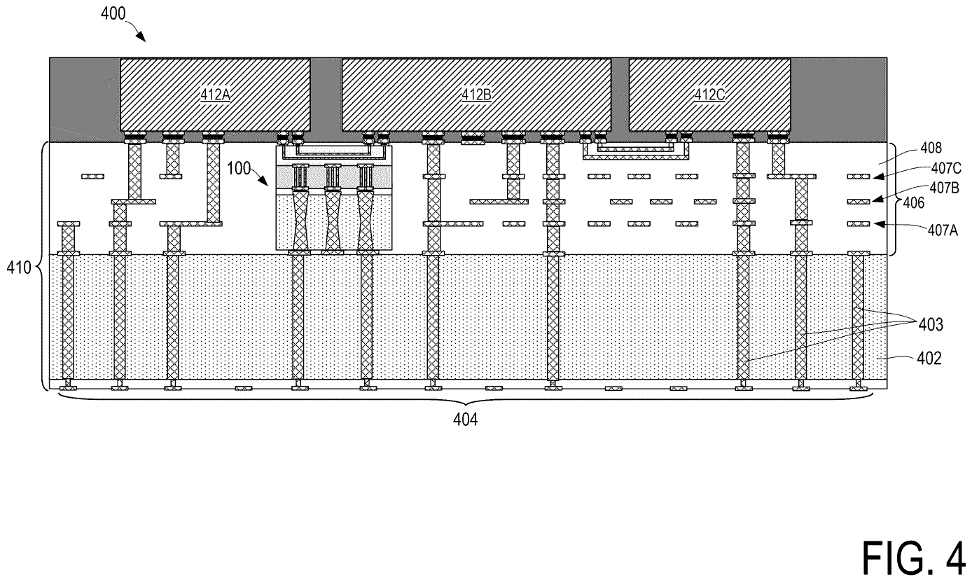

FIG. 4 illustrates an example multi-die package 400 that includes the assembly 100 of FIGS. 1A-1B embedded in interconnect layers of a package substrate 410. The package 400 includes three integrated circuit dies 412A-C coupled to a substrate 410 with a thick core layer 402 (e.g., greater than 200 um in thickness). In some embodiments, for example, the die 412A may be a central processing unit (CPU), the die 412B may be an input/output (IO) hub, and the die 412C may be a graphics processing unit (GPU). However, the dies 412 may be implemented in another manner than shown.

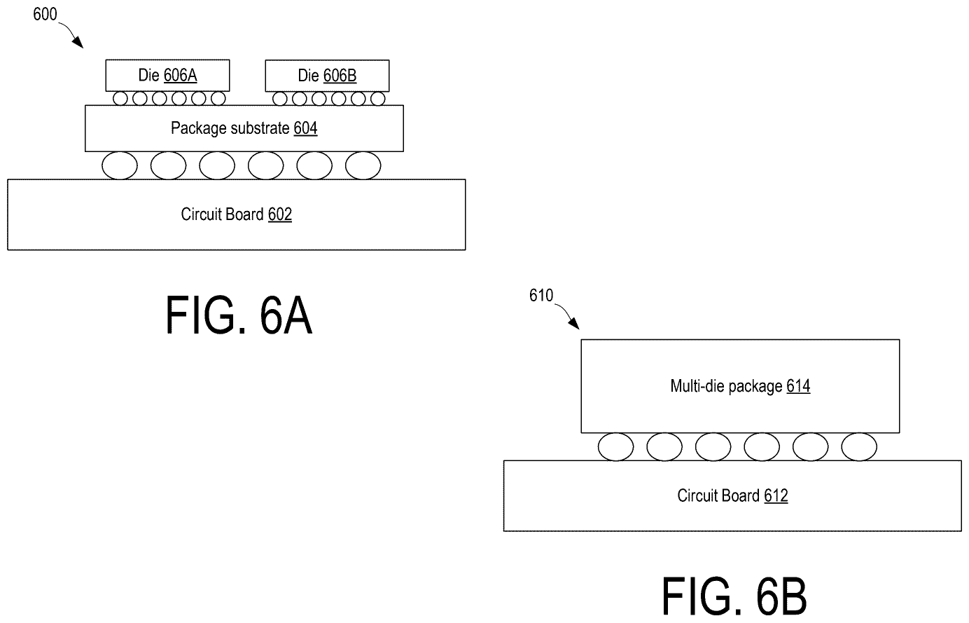

The substrate 410 includes a core layer 402 and interconnect layers 406 on the core layer 402. The core layer 402 includes vias 403 electrically connecting the top side of the core layer 402 to the pads 404 on the bottom side of the core layer 402, and the interconnect layers 406 include metallization layers 407 that include traces and vias connecting various traces of the different metallization layers 407 together. The vias 403 in the core layer 402 and the traces/vias of the metallization layers 407 together serve to electrically couple dies 412 with the pads 404, which may be then connected to a circuit board. In certain instances, the package 400 may be incorporated into the system 600 of FIG. 6B as the multi-die package 614. In some embodiments, the core layer 402 may be formed of glass or a glass-based material, while the dielectric 408 within the interconnect layers may be a mold material or a laminated material (e.g., ABF or similar materials). In other embodiments, the core layer 402 may be formed from an organic material, such as resin epoxy or epoxy reinforced with glass fiber. The core layer 402 may also be formed from inorganic material such as ceramic in certain embodiments.

The substrate 410 further includes the assembly 100 embedded inside the interconnect layers 406. The assembly 100 interconnects the dies 412A, 412B with one another while traces of the interconnect layers 407 are used to interconnect the dies 412B, 412C with one another. In some embodiments, the package 400 may be coupled to a circuit board, e.g., a motherboard or main board of a computing system, in a similar manner to the multi-die package 614 is coupled to the circuit board 612 as described below. For example, in some embodiments, the package 400 may be attached directly to a printed circuit board without an intermediate package substrate, interposer, etc. The package 400 may be implemented in a handheld computing devices, such as notebook computers, tablets, or smart phones.

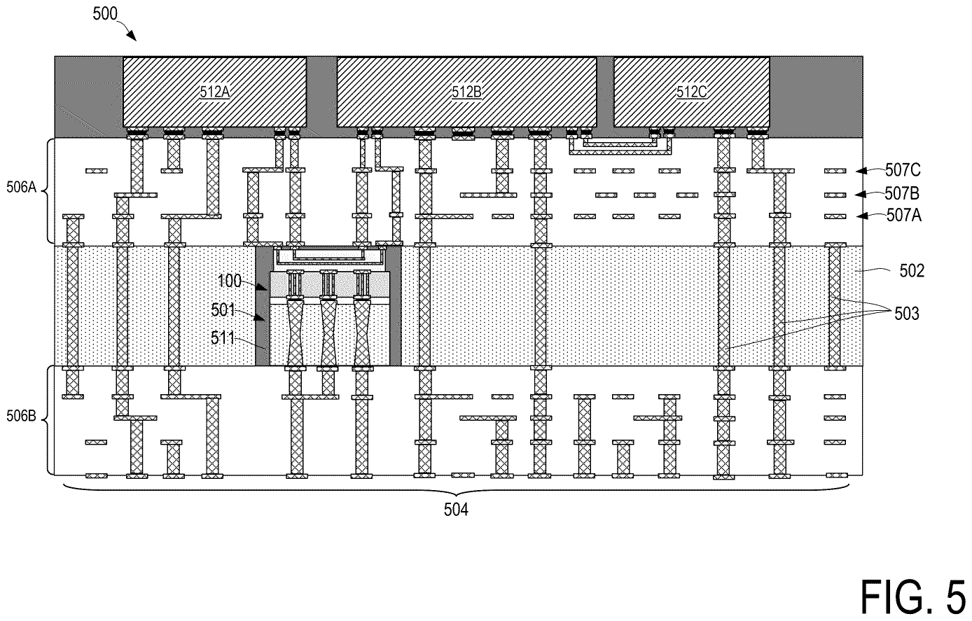

FIG. 5 illustrates an example multi-die package 500 that includes the assembly 100 of FIGS. 1A-1B embedded in a core layer of a package substrate 510. Like the previous examples, the package 500 includes three integrated circuit dies 512A-C coupled to a substrate 510 with a thick core layer 502 (e.g., greater than 200 um in thickness). In some embodiments, for example the die 512A may be a central processing unit (CPU), the die 512B may be an input/output (IO) hub, and the die 512C may be a graphics processing unit (GPU). However, the dies 512 may be implemented in another manner than shown.

The substrate 510 includes a core layer 502 and interconnect layers 506A, 506B on opposite sides of the core layer 502. The core layer 502 includes vias 503 electrically connecting the top side of the core layer 502 to the bottom side of the core layer 502, and the interconnect layers 506 include metallization layers 507 that include traces and vias connecting various traces of the different metallization layers 507 together. The vias 503 in the core layer 502 and the traces/vias of the metallization layers 507 together serve to electrically couple dies 512 with the pads 504 at the bottom of the package, which may be then connected to a circuit board as described below.

In some embodiments, the core layer 502 may be formed of glass or a glass-based material, while the dielectric 508 within the interconnect layers may be a mold material or a laminated material (e.g., ABF or similar materials). In other embodiments, the core layer 502 may be formed from an organic material. The substrate 510 defines a cavity 501 in which the assembly 100 is embedded and then encapsulated within a dielectric encapsulant material 511, e.g., similar to the encapsulant material 211 above. The encapsulant material 511 may have a high thermal conductivity and/or appropriate coefficient of thermal expansion (CTE), and such material may be chosen based on the active/passive nature of the bridge circuitry within the assembly 100 and/or the type of semiconductor material used.

The assembly 100 interconnects the dies 512A, 512B with one another while traces of the interconnect layers 507A are used to interconnect the dies 512B, 512C with one another. In some embodiments, the package 500 may be coupled to a circuit board, e.g., a motherboard or main board of a computing system, in a similar manner to the multi-die package 614 is coupled to the circuit board 612 as described below. For example, in some embodiments, the package 500 may be attached directly to a printed circuit board without an intermediate package substrate, interposer, etc. The package 500 may be implemented in a handheld computing devices, such as notebook computers, tablets, or smart phones.

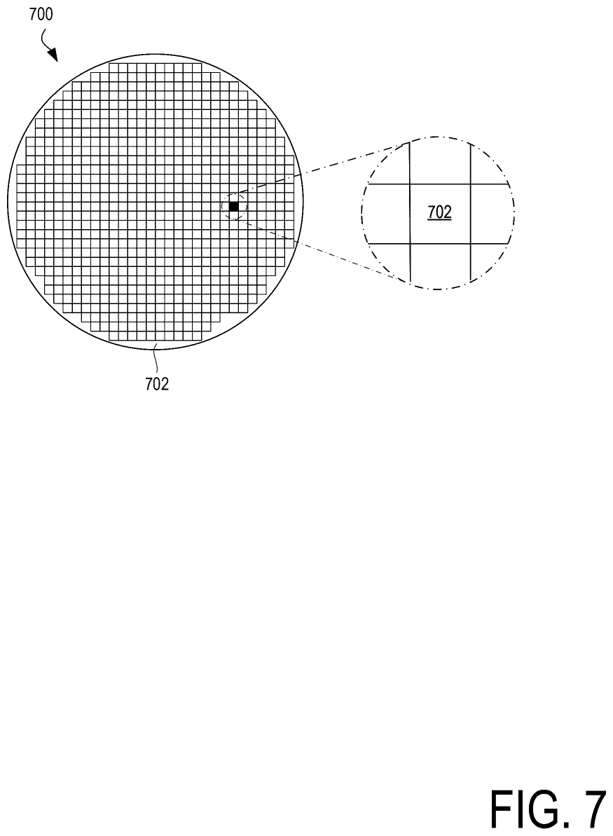

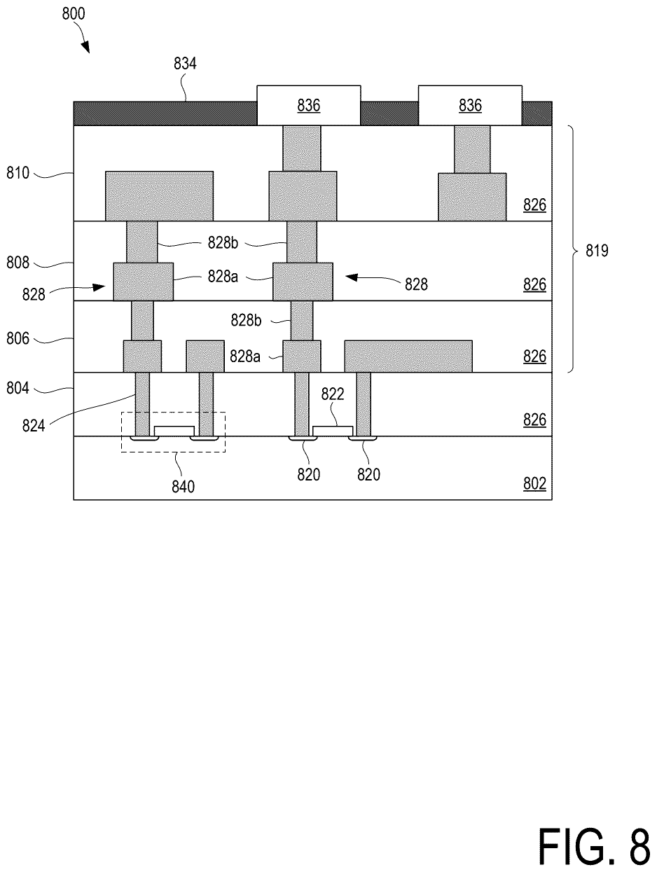

FIGS. 6A-6B illustrate example systems 600, 610 that may incorporate the glass core architectures described herein. The example system 600 of FIG. 6A includes a circuit board 602, which may be implemented as a motherboard or main board of a computer system in some embodiments. The example system 600 also includes a package substrate 604 with integrated circuit dies 606A-B attached to the package substrate 604. The dies 606 may be a packaged or unpacked integrated circuit product that includes one or more integrated circuit dies (e.g., the die 702 of FIG. 7, the integrated circuit device 800 of FIG. 8) and/or one or more other suitable components. The dies 606 can comprise one or more computing system components, such as one or more processor units (e.g., system-on-a-chip (SoC), processor core, graphics processor unit (GPU), accelerator, chipset processor), I/O controller, memory, or network interface controller.

In some embodiments, the dies 606 can comprise one or more additional active or passive devices such as capacitors, decoupling capacitors, resistors, inductors, fuses, diodes, transformers, sensors, electrostatic discharge (ESD) devices, and memory devices. In addition to comprising one or more processor units, the dies 606 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. The package substrate 604 may provide electrical connections between the dies 606 and the circuit board 602.

Similar to the system 600, the system 610 also includes a circuit board 612, which may be implemented as a motherboard or main board of a computer system in some embodiments. The system 610 also includes a multi-die package 614, which includes multiple integrated circuits/dies (e.g., 606), and interconnections between the dies in one or more metallization layers. The multi-die package 614 may include, for example, one or more silicon interposers, one or more silicon bridges embedded in the package substrate (e.g., an Intel® embedded multi-die interconnect bridge (EMIB)), or combinations thereof.

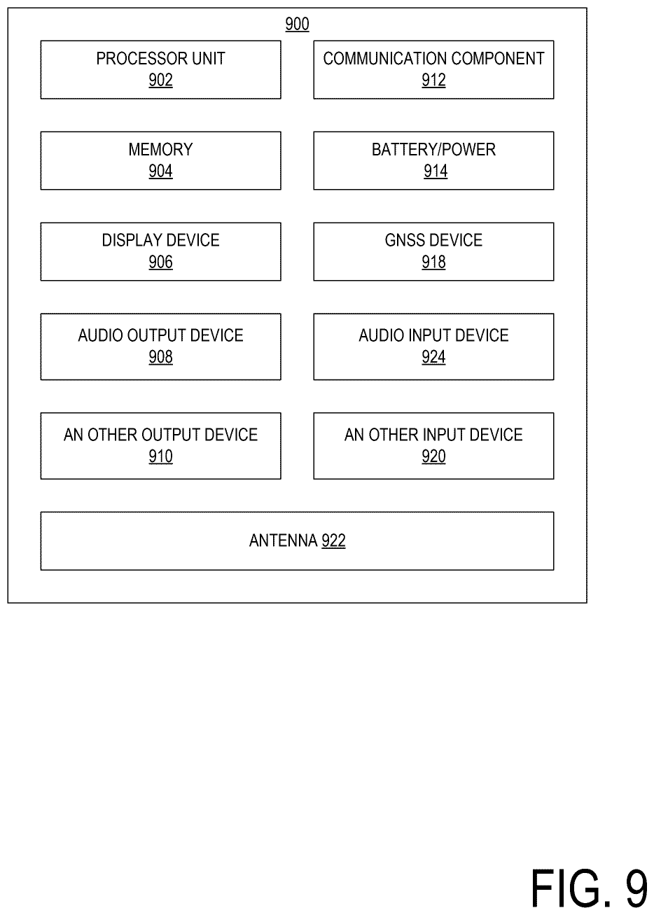

The main circuit boards 602, 612 may provide electrical connections to other components of a computer system, e.g., memory, storage, network interfaces, peripheral devices, power supplies, etc. For example, the main circuit boards 602, 612 may provide electrical connections between the dies and one or more of the components shown in FIG. 9 and described below. The main circuit board may include one or more traces and circuit components to provide interconnects between such computer system components.

FIG. 7 is a top view of a wafer 700 and dies 702 that may be implemented in or along with any of the embodiments disclosed herein. The wafer 700 may be composed of semiconductor material and may include one or more dies 702 having integrated circuit structures formed on a surface of the wafer 700. The individual dies 702 may be a repeating unit of an integrated circuit product that includes any suitable integrated circuit. After the fabrication of the semiconductor product is complete, the wafer 700 may undergo a singulation process in which the dies 702 are separated from one another to provide discrete “chips” of the integrated circuit product. The die 702 may include one or more transistors (e.g., some of the transistors 840 of FIG. 8, discussed below), supporting circuitry to route electrical signals to the transistors, passive components (e.g., signal traces, resistors, capacitors, or inductors), and/or any other integrated circuit components. In some embodiments, the wafer 700 or the die 702 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 702. For example, a memory array formed by multiple memory devices may be formed on a same die 702 as a processor unit (e.g., the processor unit 902 of FIG. 9) or other logic that is configured to store information in the memory devices or execute instructions stored in the memory array.

FIG. 8 is a cross-sectional side view of an integrated circuit device 800 that may be included in any of the embodiments disclosed herein. One or more of the integrated circuit devices 800 may be included in one or more dies 702 (FIG. 7). The integrated circuit device 800 may be formed on a die substrate 802 (e.g., the wafer 700 of FIG. 7) and may be included in a die (e.g., the die 702 of FIG. 7). The die substrate 802 may be a semiconductor substrate composed of semiconductor material systems including, for example, n-type or p-type materials systems (or a combination of both). The die substrate 802 may include, for example, a crystalline substrate formed using a bulk silicon or a silicon-on-insulator (SOI) substructure. In some embodiments, the die substrate 802 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 802. Although a few examples of materials from which the die substrate 802 may be formed are described here, any material that may serve as a foundation for an integrated circuit device 800 may be used. The die substrate 802 may be part of a singulated die (e.g., the dies 702 of FIG. 7) or a wafer (e.g., the wafer 700 of FIG. 7).

The integrated circuit device 800 may include one or more device layers 804 disposed on the die substrate 802. The device layer 804 may include features of one or more transistors 840 (e.g., metal oxide semiconductor field-effect transistors (MOSFETs)) formed on the die substrate 802. The transistors 840 may include, for example, one or more source and/or drain (S/D) regions 820, a gate 822 to control current flow between the S/D regions 820, and one or more S/D contacts 824 to route electrical signals to/from the S/D regions 820. The transistors 840 may include additional features not depicted for the sake of clarity, such as device isolation regions, gate contacts, and the like. The transistors 840 are not limited to the type and configuration depicted in FIG. 8 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Returning to FIG. 8, a transistor 840 may include a gate 822 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 840 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 840 along the source-channel-drain direction, the gate electrode may consist of a U-shaped structure that includes a bottom portion substantially parallel to the surface of the die substrate 802 and two sidewall portions that are substantially perpendicular to the top surface of the die substrate 802. In other embodiments, at least one of the metal layers that form the gate electrode may simply be a planar layer that is substantially parallel to the top surface of the die substrate 802 and does not include sidewall portions substantially perpendicular to the top surface of the die substrate 802. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 820 may be formed within the die substrate 802 adjacent to the gate 822 of individual transistors 840. The S/D regions 820 may be formed using an implantation/diffusion process or an etching/deposition process, for example. In the former process, dopants such as boron, aluminum, antimony, phosphorous, or arsenic may be ion-implanted into the die substrate 802 to form the S/D regions 820. An annealing process that activates the dopants and causes them to diffuse farther into the die substrate 802 may follow the ion-implantation process. In the latter process, the die substrate 802 may first be etched to form recesses at the locations of the S/D regions 820. An epitaxial deposition process may then be carried out to fill the recesses with material that is used to fabricate the S/D regions 820. In some implementations, the S/D regions 820 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 820 may be formed using one or more alternate semiconductor materials such as germanium or a group III-V material or alloy. In further embodiments, one or more layers of metal and/or metal alloys may be used to form the S/D regions 820.

Electrical signals, such as power and/or input/output (I/O) signals, may be routed to and/or from the devices (e.g., transistors 840) of the device layer 804 through one or more interconnect layers disposed on the device layer 804 (illustrated in FIG. 8 as interconnect layers 806-810). For example, electrically conductive features of the device layer 804 (e.g., the gate 822 and the S/D contacts 824) may be electrically coupled with the interconnect structures 828 of the interconnect layers 806-810. The one or more interconnect layers 806-810 may form a metallization stack (also referred to as an “ILD stack”) 819 of the integrated circuit device 800.

The interconnect structures 828 may be arranged within the interconnect layers 806-810 to route electrical signals according to a wide variety of designs; in particular, the arrangement is not limited to the particular configuration of interconnect structures 828 depicted in FIG. 8. Although a particular number of interconnect layers 806-810 is depicted in FIG. 8, embodiments of the present disclosure include integrated circuit devices having more or fewer interconnect layers than depicted.

In some embodiments, the interconnect structures 828 may include lines 828a and/or vias 828b filled with an electrically conductive material such as a metal. The lines 828a may be arranged to route electrical signals in a direction of a plane that is substantially parallel with a surface of the die substrate 802 upon which the device layer 804 is formed. For example, the lines 828a may route electrical signals in a direction in and out of the page and/or in a direction across the page from the perspective of FIG. 8. The vias 828b may be arranged to route electrical signals in a direction of a plane that is substantially perpendicular to the surface of the die substrate 802 upon which the device layer 804 is formed. In some embodiments, the vias 828b may electrically couple lines 828a of different interconnect layers 806-810 together.

The interconnect layers 806-810 may include a dielectric material 826 disposed between the interconnect structures 828, as shown in FIG. 8. In some embodiments, dielectric material 826 disposed between the interconnect structures 828 in different ones of the interconnect layers 806-810 may have different compositions; in other embodiments, the composition of the dielectric material 826 between different interconnect layers 806-810 may be the same. The device layer 804 may include a dielectric material 826 disposed between the transistors 840 and a bottom layer of the metallization stack as well. The dielectric material 826 included in the device layer 804 may have a different composition than the dielectric material 826 included in the interconnect layers 806-810; in other embodiments, the composition of the dielectric material 826 in the device layer 804 may be the same as a dielectric material 826 included in any one of the interconnect layers 806-810.

A first interconnect layer 806 (referred to as Metal 1 or “M1”) may be formed directly on the device layer 804. In some embodiments, the first interconnect layer 806 may include lines 828a and/or vias 828b, as shown. The lines 828a of the first interconnect layer 806 may be coupled with contacts (e.g., the S/D contacts 824) of the device layer 804. The vias 828b of the first interconnect layer 806 may be coupled with the lines 828a of a second interconnect layer 808.

The second interconnect layer 808 (referred to as Metal 2 or “M2”) may be formed directly on the first interconnect layer 806. In some embodiments, the second interconnect layer 808 may include via 828b to couple the line 828a of the second interconnect layer 808 with the lines 828a of a third interconnect layer 810. Although the lines 828a and the vias 828b are structurally delineated with a line within individual interconnect layers for the sake of clarity, the lines 828a and the vias 828b may be structurally and/or materially contiguous (e.g., simultaneously filled during a dual-damascene process) in some embodiments.

The third interconnect layer 810 (referred to as Metal 3 or “M3”) (and additional interconnect layers, as desired) may be formed in succession on the second interconnect layer 808 according to similar techniques and configurations described in connection with the second interconnect layer 808 or the first interconnect layer 806. In some embodiments, the interconnect layers that are “higher up” in the metallization stack 819 in the integrated circuit device 800 (i.e., farther away from the device layer 804) may be thicker that the interconnect layers that are lower in the metallization stack 819, with lines 828a and vias 828b in the higher interconnect layers being thicker than those in the lower interconnect layers.

The integrated circuit device 800 may include a solder resist material 834 (e.g., polyimide or similar material) and one or more conductive contacts 836 formed on the interconnect layers 806-810. In FIG. 8, the conductive contacts 836 are illustrated as taking the form of bond pads. The conductive contacts 836 may be electrically coupled with the interconnect structures 828 and configured to route the electrical signals of the transistor(s) 840 to external devices. For example, solder bonds may be formed on the one or more conductive contacts 836 to mechanically and/or electrically couple an integrated circuit die including the integrated circuit device 800 with another component (e.g., a printed circuit board or a package substrate, e.g., 112). The integrated circuit device 800 may include additional or alternate structures to route the electrical signals from the interconnect layers 806-810; for example, the conductive contacts 836 may include other analogous features (e.g., posts) that route the electrical signals to external components.

In some embodiments in which the integrated circuit device 800 is a double-sided die, the integrated circuit device 800 may include another metallization stack (not shown) on the opposite side of the device layer(s) 804. This metallization stack may include multiple interconnect layers as discussed above with reference to the interconnect layers 806-810, to provide conductive pathways (e.g., including conductive lines and vias) between the device layer(s) 804 and additional conductive contacts (not shown) on the opposite side of the integrated circuit device 800 from the conductive contacts 836.

In other embodiments in which the integrated circuit device 800 is a double-sided die, the integrated circuit device 800 may include one or more through silicon vias (TSVs) through the die substrate 802; these TSVs may make contact with the device layer(s) 804, and may provide conductive pathways between the device layer(s) 804 and additional conductive contacts (not shown) on the opposite side of the integrated circuit device 800 from the conductive contacts 836. In some embodiments, TSVs extending through the substrate can be used for routing power and ground signals from conductive contacts on the opposite side of the integrated circuit device 800 from the conductive contacts 836 to the transistors 840 and any other components integrated into the die, and the metallization stack 819 can be used to route I/O signals from the conductive contacts 836 to transistors 840 and any other components integrated into the die.

Multiple integrated circuit devices 800 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

FIG. 9 is a block diagram of an example electrical device 900 that may include one or more of the embodiments disclosed herein. For example, any suitable ones of the components of the electrical device 900 may include one or more of integrated circuit devices 800, or integrated circuit dies 702 disclosed herein. A number of components are illustrated in FIG. 9 as included in the electrical device 900, but any one or more of these components may be omitted or duplicated, as suitable for the application. In some embodiments, some or all of the components included in the electrical device 900 may be attached to one or more motherboards mainboards, or system boards. In some embodiments, one or more of these components are fabricated onto a single system-on-a-chip (SoC) die.

Additionally, in various embodiments, the electrical device 900 may not include one or more of the components illustrated in FIG. 9, but the electrical device 900 may include interface circuitry for coupling to the one or more components. For example, the electrical device 900 may not include a display device 906, but may include display device interface circuitry (e.g., a connector and driver circuitry) to which a display device 906 may be coupled. In another set of examples, the electrical device 900 may not include an audio input device 924 or an audio output device 908, but may include audio input or output device interface circuitry (e.g., connectors and supporting circuitry) to which an audio input device 924 or audio output device 908 may be coupled.

The electrical device 900 may include one or more processor units 902 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 902 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 900 may include a memory 904, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 904 may include memory that is located on the same integrated circuit die as the processor unit 902. This memory may be used as cache memory (e.g., Level 1 (L1), Level 2(L2 ), Level 3(L3 ), Level 4(L4 ), Last Level Cache (LLC)) and may include embedded dynamic random access memory (eDRAM) or spin transfer torque magnetic random access memory (STT-MRAM).

In some embodiments, the electrical device 900 can comprise one or more processor units 902 that are heterogeneous or asymmetric to another processor unit 902 in the electrical device 900. There can be a variety of differences between the processing units 902 in a system in terms of a spectrum of metrics of merit including architectural, microarchitectural, thermal, power consumption characteristics, and the like. These differences can effectively manifest themselves as asymmetry and heterogeneity among the processor units 902 in the electrical device 900.

In some embodiments, the electrical device 900 may include a communication component 912 (e.g., one or more communication components). For example, the communication component 912 can manage wireless communications for the transfer of data to and from the electrical device 900. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 912 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 912 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 912 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 912 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 912 may operate in accordance with other wireless protocols in other embodiments. The electrical device 900 may include an antenna 922 to facilitate wireless communications and/or to receive other wireless communications (such as AM or FM radio transmissions).

In some embodiments, the communication component 912 may manage wired communications, such as electrical, optical, or any other suitable communication protocols (e.g., IEEE 802.3 Ethernet standards). As noted above, the communication component 912 may include multiple communication components. For instance, a first communication component 912 may be dedicated to shorter-range wireless communications such as Wi-Fi or Bluetooth, and a second communication component 912 may be dedicated to longer-range wireless communications such as global positioning system (GPS), EDGE, GPRS, CDMA, WiMAX, LTE, EV-DO, or others. In some embodiments, a first communication component 912 may be dedicated to wireless communications, and a second communication component 912 may be dedicated to wired communications.

The electrical device 900 may include battery/power circuitry 914. The battery/power circuitry 914 may include one or more energy storage devices (e.g., batteries or capacitors) and/or circuitry for coupling components of the electrical device 900 to an energy source separate from the electrical device 900 (e.g., AC line power).

The electrical device 900 may include a display device 906 (or corresponding interface circuitry, as discussed above). The display device 906 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 900 may include an audio output device 908 (or corresponding interface circuitry, as discussed above). The audio output device 908 may include any embedded or wired or wirelessly connected external device that generates an audible indicator, such speakers, headsets, or earbuds.

The electrical device 900 may include an audio input device 924 (or corresponding interface circuitry, as discussed above). The audio input device 924 may include any embedded or wired or wirelessly connected device that generates a signal representative of a sound, such as microphones, microphone arrays, or digital instruments (e.g., instruments having a musical instrument digital interface (MIDI) output). The electrical device 900 may include a Global Navigation Satellite System (GNSS) device 918 (or corresponding interface circuitry, as discussed above), such as a Global Positioning System (GPS) device. The GNSS device 918 may be in communication with a satellite-based system and may determine a geolocation of the electrical device 900 based on information received from one or more GNSS satellites, as known in the art.

The electrical device 900 may include another output device 910 (or corresponding interface circuitry, as discussed above). Examples of the other output device 910 may include an audio codec, a video codec, a printer, a wired or wireless transmitter for providing information to other devices, or an additional storage device.

The electrical device 900 may include another input device 920 (or corresponding interface circuitry, as discussed above). Examples of the other input device 920 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 900 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 900 may be any other electronic device that processes data. In some embodiments, the electrical device 900 may comprise multiple discrete physical components. Given the range of devices that the electrical device 900 can be manifested as in various embodiments, in some embodiments, the electrical device 900 can be referred to as a computing device or a computing system.

In the above description, various aspects of the illustrative implementations have been described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials, and configurations have been set forth to provide a thorough understanding of the illustrative implementations. However, it will be apparent to one skilled in the art that the present disclosure may be practiced without all of the specific details. In other instances, well-known features have been omitted or simplified in order not to obscure the illustrative implementations.

Further, concepts described herein are illustrated by way of example and not by way of limitation in the accompanying figures. It will be understood that in the examples shown and described further below, the figures may not be drawn to scale and may not include all possible layers and/or circuit components. In addition, it will be understood that although certain figures illustrate transistor designs with source/drain regions, electrodes, etc. having orthogonal (e.g., perpendicular) boundaries, embodiments herein may implement such boundaries in a substantially orthogonal manner (e.g., within +/−5 or 10 degrees of orthogonality) due to fabrication methods used to create such devices or for other reasons. Where considered appropriate, reference labels may have been repeated between certain Figures to indicate corresponding or analogous elements.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C). For the purposes of the present disclosure, the phrase “A and at least one of B and C” means (A and B), (A and C), or (A and B and C).

The terms “over,” “under,” “between,” “above,” and “on” as used herein may refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components. As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

The above description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 is an apparatus comprising: a substrate; and an assembly in the substrate, the assembly comprising: an interposer comprising vias electrically coupling a first side of the interposer and a second side of the interposer opposite the first side; and an interconnect bridge circuitry die coupled to the first side of the interposer, the interconnect bridge circuitry die comprising circuitry to connect first conductive contacts on an upper surface of the die to second conductive contacts on the upper surface of the die.

Example 2 includes the apparatus of Example 1, wherein a ratio of height to diameter of the vias of the interposer is greater than 20:1.

Example 3 includes the apparatus of Example 1 or 2, wherein the interposer comprises a glass layer comprising Silicon at least 23% by weight and Oxygen at least 26% by weight.

Example 4 includes the apparatus of any one of Examples 1-3, wherein the substrate comprises a core layer and the assembly is embedded in the core layer.

Example 5 includes the apparatus of Example 4, wherein a thickness of the assembly is approximately equal to a thickness of layer of the core layer.

Example 6 includes the apparatus of any one of Examples 4-5, wherein the core layer defines a cavity and the assembly is embedded in the cavity of the core layer and encompassed with dielectric material.

Example 7 includes the apparatus of any one of Examples 4-6, further comprising first interconnect layers above the core layer and second interconnect layers below the core layer, the core layer comprising vias electrically coupling the first interconnect layers and the second interconnect layers.

Example 8 includes the apparatus of any one of Examples 4-7, wherein the core layer comprises glass, the core layer comprising Silicon at least 23% by weight and Oxygen at least 26% by weight.

Example 9 includes the apparatus of any one of Examples 1-3, wherein the substrate comprises a core layer and interconnect layers on the core layer, the assembly embedded in the interconnect layers.

Example 10 includes the apparatus of any one of Examples 1-9, wherein the interconnect bridge circuitry die comprises passive circuit components.

Example 11 includes the apparatus of any one of Examples 1-10, wherein the interconnect bridge circuitry die comprises active circuit components.

Example 12 includes the apparatus of any one of Examples 1-11, further comprising a first integrated circuit die coupled to the first conductive contacts of the interconnect bridge circuitry die and a second integrated circuit die coupled to the second conductive contacts of the interconnect bridge circuitry die.

Example 13 includes the apparatus of any one of Examples 1-12, further comprising a circuit board coupled to the substrate.

Example 14 is an apparatus comprising: a package substrate comprising a bridge circuitry assembly embedded therein, the bridge circuitry assembly comprising: an interconnect bridge circuitry die comprising circuitry interconnecting conductive contacts on a first side of the die; and a glass interposer coupled to a second side of the die opposite the first side of the die, the glass interposer comprising through glass vias (TGVs).

Example 15 includes the apparatus of Example 14, wherein the TGVs have an aspect ratio greater than 20:1.

Example 16 includes the apparatus of Example 14 or 15, wherein the glass comprises Silicon at least 23% by weight and Oxygen at least 26% by weight.

Example 17 includes the apparatus of any one of Examples 14-16, wherein the package substrate comprises a core layer and at least one interconnect layer on the core layer, and the assembly is in a cavity defined by the core layer.

Example 18 includes the apparatus of Example 17, wherein a thickness of the assembly is approximately equal to a thickness of layer of the core layer.

Example 19 includes the apparatus of any one of Examples 17-18, further comprising first interconnect layers above the core layer and second interconnect layers below the core layer, the core layer comprising vias electrically coupling the first interconnect layers and the second interconnect layers.

Example 20 includes the apparatus of any one of Examples 17-19, wherein the core layer is glass comprising Silicon at least 23% by weight and Oxygen at least 26% by weight.

Example 21 includes the apparatus of any one of Examples 14-16, wherein the package substrate comprises a core layer and interconnect layers on the core layer, and the assembly in the interconnect layers.

Example 22 includes the apparatus of any one of Examples 14-21, wherein the interconnect bridge circuitry die comprises passive circuit components.

Example 23 includes the apparatus of any one of Examples 14-22, wherein the interconnect bridge circuitry die comprises active circuit components.

Example 24 includes the apparatus of any one of Examples 14-23, further comprising a first integrated circuit die coupled to the first conductive contacts of the interconnect bridge circuitry die and a second integrated circuit die coupled to the second conductive contacts of the interconnect bridge circuitry die.

Example 25 includes the apparatus of any one of Examples 14-24, further comprising a circuit board coupled to the substrate.

Example 26 is an integrated circuit package comprising: a package substrate; a first integrated circuit die coupled to a top side of the package substrate; and a second integrated circuit die coupled to the top side of the package substrate; wherein the package substrate comprises: first traces or vias electrically coupling the first integrated circuit die with first pads on a bottom side of the package substrate; second traces or vias electrically coupling the second integrated circuit die with second pads on the bottom side of the package substrate; and an assembly comprising: a bridge circuitry die comprising circuitry electrically coupling the first integrated circuit die and the second integrated circuit die; and a glass interposer coupled to the bridge circuitry die, the glass interposer comprising through glass vias (TGVs).

Example 27 includes the integrated circuit package of Example 26, wherein the TGVs have an aspect ratio greater than 20:1.

Example 28 includes the integrated circuit package of any one of Examples 26-27, wherein the glass of the interposer comprises Silicon at least 23% by weight and Oxygen at least 26% by weight.

Example 29 includes the integrated circuit package of any one of Examples 26-28, wherein the package substrate comprises a core layer and at least one interconnect layer on the core layer, and the assembly is in a cavity defined by the core layer.

Example 30 includes the integrated circuit package of any one of Examples 26-28, wherein the package substrate comprises a core layer and interconnect layers on the core layer, and the assembly in the interconnect layers.

Example 31 includes the integrated circuit package of any one of Examples 26-30, wherein the interconnect bridge circuitry die comprises passive circuit components.

Example 32 includes the integrated circuit package of any one of Examples 26-31, wherein the interconnect bridge circuitry die comprises active circuit components.

Example 33 is a system comprising: a circuit board; and the integrated circuit package coupled to the circuit board, the integrated circuit package according to any one of Examples 26-32.

Example 34 includes the system of Example 33, wherein the first integrated circuit die comprises a processor.

1. An apparatus comprising:
a substrate; and
an assembly in the substrate, the assembly comprising:
an interposer comprising vias electrically coupling a first side of the interposer and a second side of the interposer opposite the first side; and
an interconnect bridge circuitry die coupled to the first side of the interposer, the interconnect bridge circuitry die comprising circuitry to connect first conductive contacts on an upper surface of the die to second conductive contacts on the upper surface of the die.

2. The apparatus of claim 1, wherein a ratio of height to diameter of the vias of the interposer is greater than 20:1.

3. The apparatus of claim 1, wherein the interposer comprises a glass layer comprising Silicon at least 23% by weight and Oxygen at least 26% by weight.

4. The apparatus of claim 1, wherein the substrate comprises a core layer and the assembly is embedded in the core layer.

5. The apparatus of claim 4, wherein the core layer defines a cavity and the assembly is embedded in the cavity of the core layer and encompassed with dielectric material.

6. The apparatus of claim 4, further comprising first interconnect layers above the core layer and second interconnect layers below the core layer, the core layer comprising vias electrically coupling the first interconnect layers and the second interconnect layers.

7. The apparatus of claim 4, wherein the core layer comprises glass, the core layer comprising Silicon at least 23% by weight and Oxygen at least 26% by weight.

8. The apparatus of claim 1, wherein the substrate comprises a core layer and interconnect layers on the core layer, the assembly embedded in the interconnect layers.

9. The apparatus of claim 1, further comprising a first integrated circuit die coupled to the first conductive contacts of the interconnect bridge circuitry die and a second integrated circuit die coupled to the second conductive contacts of the interconnect bridge circuitry die.

10. The apparatus of claim 1, further comprising a circuit board coupled to the substrate.

11. An apparatus comprising:
a package substrate comprising a bridge circuitry assembly embedded therein, the bridge circuitry assembly comprising:
an interconnect bridge circuitry die comprising circuitry interconnecting conductive contacts on a first side of the die; and
a glass interposer coupled to a second side of the die opposite the first side of the die, the glass interposer comprising through glass vias (TGVs).

12. The apparatus of claim 11, wherein the TGVs have an aspect ratio greater than 20:1.

13. The apparatus of claim 11, wherein the package substrate comprises a core layer and at least one interconnect layer on the core layer, and the assembly is in a cavity defined by the core layer.

14. The apparatus of claim 13, further comprising first interconnect layers above the core layer and second interconnect layers below the core layer, the core layer comprising vias electrically coupling the first interconnect layers and the second interconnect layers.

15. The apparatus of claim 11, wherein the package substrate comprises a core layer and interconnect layers on the core layer, and the assembly in the interconnect layers.

16. The apparatus of claim 11, further comprising a first integrated circuit die coupled to the interconnect bridge circuitry die and a second integrated circuit die coupled to the interconnect bridge circuitry die.

17. The apparatus of claim 11, further comprising a circuit board coupled to the substrate.

18. An integrated circuit package comprising:
a package substrate;
a first integrated circuit die coupled to a top side of the package substrate; and
a second integrated circuit die coupled to the top side of the package substrate;
wherein the package substrate comprises:
first traces or vias electrically coupling the first integrated circuit die with first pads on a bottom side of the package substrate;
second traces or vias electrically coupling the second integrated circuit die with second pads on the bottom side of the package substrate; and
an assembly comprising:
a bridge circuitry die comprising circuitry electrically coupling the first integrated circuit die and the second integrated circuit die; and
a glass interposer coupled to the bridge circuitry die, the glass interposer comprising through glass vias (TGVs).

19. The integrated circuit package of claim 18, wherein the TGVs have an aspect ratio greater than 20:1.

20. The integrated circuit package of claim 18, wherein the package substrate comprises a core layer and at least one interconnect layer on the core layer, and the assembly is in a cavity defined by the core layer.
